(19) United States
(12) Patent Application Publication
(10) Pub. No.: US 2025/0188644 A1
(43) Pub. Date: Jun. 12, 2025

(54) METHOD OF DEPOSITION OF A THIN SULFIDE LAYER OF A TRANSITION METAL OR OF ONE OF ITS ALLOYS

(71) Applicant: Commissariat à l'Énergie Atomique et aux Énergies Alternatives, Paris (FR)

(72) Inventor: Stéphane Cadot, Grenoble Cedex 9 (FR)

(73) Assignee: Commissariat à l'Énergie Atomique et aux Énergies Alternatives, Paris (FR)

(21) Appl. No.: 18/967,921

(22) Filed: Dec. 4, 2024

(30) Foreign Application Priority Data
Dec. 6, 2023 (FR) 2313672

(51) Int. Cl. C30B 28/14; C23C 16/30; C23C 16/44; C23C 16/455; C23C 16/46; C23C 16/56; C30B 29/46; C30B 29/68

(52) U.S. Cl. CPC C30B 28/14; C23C 16/305; C23C 16/4408; C23C 16/45529; C23C 16/45553; C23C 16/46; C23C 16/56; C30B 29/46; C30B 29/68

(57) ABSTRACT

A method of the vapor-phase deposition of a sulfide layer of a transition metal by ALD according to the following cycle: exposing a substrate to a precursor of the transition metal, whereby an intermediate layer is formed, purging the reactor, exposing the intermediate layer to a precursor of sulfur, purging the reactor, the substrate being at a temperature in the range from 20° C. to 250° C. during the cycle, where the cycle can be repeated several times with the same precursors or with different precursors, the precursor of the transition metal being selected from among molybdenum oxyhalides, tungsten oxyhalides, vanadium halides, niobium halides, and tantalum halides.

### CROSS-REFERENCE TO RELATED APPLICATIONS

This application claims priority to French application number 2313672, filed Dec. 6, 2023, the contents of which is incorporated herein by reference in its entirety.

### TECHNICAL FIELD

The present disclosure generally concerns the deposition of thin films of transition metal sulfides, in particular thin films of molybdenum, tungsten, vanadium, niobium, or tantalum sulfide and/or of one of their alloys. Such layers are particularly advantageous in the microelectronics industry.

### PRIOR ART

Transition metal dichalcogenides (TMDs) currently arouse a great interest due to their unique optoelectronic properties when they are insulated to the state of one or a few atomic monolayers, and to their potential for the miniaturization and the functional diversification of electronic components. In particular, the use of semiconductor TMDs such as MoS₂ and WS₂ would enable to further advance in the miniaturization of transistors, offering a better electrostatic control than silicon on channel dimensions shorter than 10 nm.

The forming of such components is currently limited by the difficulty of integrating the TMD material without degrading its structure or altering its properties. The lamellar structure of TMDs and the resulting low adhesion also generate a number of integration problems linked to the high complexity of the lithography stages. In this context, it seems important to develop methods for depositing TMDs allowing their deployment in 3D architectures (as opposed to the strategy which consists of growing the TMD on a dedicated substrate and then transferring it onto a planarized structure), to be able to protect the TMD material all throughout the integration steps and guarantee its integrity. Another critical point in the forming of devices based on semiconductor TMDs is the difficulty of forming high-performance electrical contacts.

Semi-metallic TMDs such as VSₓ (particularly VS₂, V₃S₄, and V₅S₈ and all other self-intercalation compounds of VS₂), NbS₂ or TaS₂ are among the highest-performance metals for contacting MoS₂ or WS₂ with low contact resistance. They also have the advantage of being very similar to MoS₂ and WS₂ both chemically and crystallographically, and thus of forming a clean, low-stress, thermally stable interface, and free of other heteroelements such as oxygen or nitrogen which might alter the properties of the TMD. Finally, group-5 elements (V, Nb, Ta) enable to induce a p-type doping in group-6 semiconductor TMDs (MoS₂ and WS₂, naturally n-doped by the presence of sulfur vacancies) and thus control the polarity of charge carriers.

Currently, there exist two main ways of producing thin films of transition metal sulfide.

A first way consists of depositing the material by chemical vapor deposition (CVD).

For example, in US application 2019/0378898 A1, CVD is used to deposit layers of MoS₂ and WS₂. The precursors are, for example, Mo(CO)₆ and W(CO)₆ and diethyl sulfide.

However, with CVD depositions, it is difficult to achieve a good control of nucleation and thus of the uniformity of the deposited layer. Further, it is not possible to deposit TMD layers on substrates having architectures with a high form factor (in nano-cavities, for example). The introduction of group-5 metals as dopants, or the forming of heterostructures of TMDs of groups 5 and 6, is also difficult to implement in CVD, since the deposition conditions directly aim at the forming of crystals having the right crystalline phase, and each material will require a very accurate adjustment of temperature and of the partial pressures of reactants.

A second way consists of depositing the material by atomic layer deposition (ALD). For this type of deposition, the precursors are used sequentially and not in a mixture as in the case of a deposition by CVD. ALD depositions enable to have a good control of the uniformity, even in architectures having a high form factor, and more easily allow than CVD the forming of heterostructures or the mixing of a plurality of metals to form alloys of well-defined composition. However, to ensure a uniform growth of ultra-thin (typically smaller than 5 nm) continuous TMD layers by ALD, the material must be deposited in amorphous form (that is, at low temperature), which implies the need for a post-deposition crystallization anneal step. The material obtained by this method in 2 steps typically has a smaller grain size than the materials obtained by CVD growth. Possibly, a thermal sulfurization step before or during the anneal enables to correct if necessary the stoichiometry of TMD.

For example, document US 2015/0211112 A1 describes the deposition of MoS₂ by ALD. Mo precursors are non-halogenated mono-metallic or bi-metallic compounds. These compounds are non-halogenated. The sulfur-containing co-reactant is H₂S or 1,2-ethanedithiol. An optional crystallization anneal may be implemented after the deposition.

According to another example, document U.S. Pat. No. 11,142,824 B2 describes the deposition of a molybdenum metal layer by ALD at low temperature (lower than 300° C.) using the MoF₆/Si₂H₆ precursor pair. The molybdenum layer is then converted into MoS₂ by a sulfidation heat treatment under H₂S at a temperature in the range from 300 to 600° C.

In document U.S. Pat. No. 9,863,039 B2, a MoS₂ layer is formed by sequentially depositing the Mo(CO)₆ precursors and the dimethyl sulfide at a temperature of 100-120° C. The heat treatment to crystallize the MoS₂ layer is carried out at a temperature in the range from 400 to 1000° C.

Document WO 2016/191432 A1 describes a method of ALD deposition of TMD layers, in particular Mo and W sulfides, selenides, and tellurides. The Mo and W precursors are beta-diketonates, and the chalcogen precursors are, for example, H₂S, H₂Se, or H₂Te, Me₂S, Me₂Se, and Me₂Te. The deposition temperature is preferably between 250° C. and 600° C. A plurality of ALD depositions were carried out by using precursors Mo(thd)₃ and H₂S with deposition temperatures ranging from 175° C. to 500° C. No deposition of MoS₂ was observed at deposition temperatures between 175° C. and 350° C. The quantity of film deposited on the substrates appears to increase from 375° C. onwards. The highest growth rates were obtained at a deposition temperature of approximately 500° C.

It should however be noted that the deposition temperatures used in some of these methods may lead to the growth of a directly crystalline material (typically when the deposition temperature is higher than 150-200° C.), which is not optimal for the obtaining of ultra-thin (having a thickness smaller than 5 nm), smooth (not very rough), and continuous layers.

Further, most of these methods do not allow the deposition of heterostructures or of alloys associating group-5 and -6 transition metals.

### SUMMARY OF THE INVENTION

There exists a need for a deposition process that can form a layer of transition metal sulfide or an alloy thereof with low roughness and good crystalline quality.

This aim is achieved by a process for the vapor-phase deposition of a sulfide layer of a transition metal or an alloy thereof, the process comprising an atomic layer deposition step according to the following cycle:
exposing a substrate to a transition metal precursor, whereby an intermediate layer is formed on the substrate,
purging the reactor,
exposing the intermediate layer to a precursor of sulfur,
purging the reactor,
the substrate being at a temperature in the range from 20° C. to 250° C. during the cycle,
where the cycle may be repeated several times, the precursor of the transition metal and/or the precursor of sulfur may be identical or different during the repetitions of the cycle, the precursor of the transition metal being selected from molybdenum oxyhalides, tungsten oxyhalides, vanadium halides, niobium halides, and tantalum halides.

According to a specific embodiment, the precursor of the transition metal is selected from among MoO₂Cl₂, MoOCl₄, WOCl₄, VCl₄, NbCl₅, and TaCl₅.

According to a specific embodiment, the precursor of sulfur is selected from among hydrogen sulfide, hydrogen polysulfides, and thiols, preferably dithiols.

According to a specific embodiment, the precursor of sulfur is selected from among 1,2-ethanedithiol, 1,2-propanedithiol, and 1,3-propanedithiol.

According to a specific embodiment, after the step of atomic layer deposition, the method comprises a sulfurization step during which the substrate is exposed to a sulfur-containing molecule possessing at least one sulfur-hydrogen or sulfur-carbon bond, at a temperature in the range from 250° C. to 1150° C., preferably from 300° C. to 400° C.

Advantageously, the sulfur-containing molecule is a dithiol, preferably 1,2-ethanedithiol.

According to a specific embodiment, after the step of atomic layer deposition, or after the sulfurization step, an anneal step is carried out.

Advantageously, the anneal step is carried out in an inert atmosphere at a temperature in the range from 400° C. to 1,150° C., preferably from 650° C. to 950° C.

According to a specific embodiment, the substrate is at a temperature in the range from 50° C. to 150° C., preferably from 80° C. to 120° C., during the cycle.

According to a specific embodiment, the precursor of the transition metal is selected from among MoO₂Cl₂, MoOCl₄, WOCl₄, and VCl₄ and the precursor of sulfur is 1,2-ethanedithiol.

This aim is also achieved by a device comprising a substrate covered by a thin crystalline layer made of molybdenum, tungsten, vanadium, niobium, or tantalum sulfide or of one of their alloys such as Mo(V)S₂ or W(V)S₂, the thin layer having a thickness smaller than 100 nm, preferably smaller than 20 nm, even more preferably smaller than 10 nm, the crystals of the thin layer being oriented, their crystallographic plane (001) being parallel to the plane of the substrate.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 is a functional diagram of an ALD cycle according to a specific embodiment of the invention,

FIG. 2 is a STEM image (HAADF) of a MoS₂ (1 nm)/VSₓ (5 nm) heterostructure obtained according to a specific embodiment of the method.

### DESCRIPTION OF EMBODIMENTS

Unless otherwise specified, the expression “approximately” signifies to within 10%, preferably to within 5%, and the expression “in the range from . . . to . . . ” signifies that the limits are included.

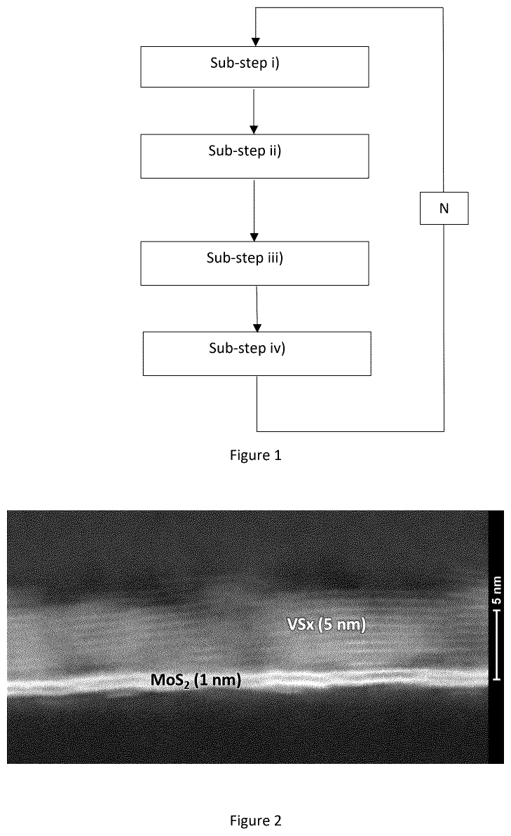

There will now be described in further detail the method of atomic layer deposition (ALD) of a thin film of a sulfide of a transition metal or of a sulfide of an alloy of transition metals. The method comprises the following steps:
a) performing the ALD deposition cycle according to the following sub-steps (FIG. 1):
   exposing a substrate to a precursor of the transition metal, whereby an intermediate layer is formed on the substrate (sub-step i)),
   purging the reactor (sub-step ii)),
   exposing the substrate and the intermediate layer to a precursor of sulfur (sub-step iii)), whereby a sulfide layer of a transition metal is formed,
   purging the reactor (sub-step iv),
b) preferably, carrying out a sulfurization step, for example at a temperature higher than 250° C.,
c) preferably, performing an anneal, advantageously in an inert atmosphere, and preferably at a temperature higher than 400° C.

Sulfurization step b) and anneal step c) may be one and the same step.

The deposition cycle may be repeated N times, with N an integer (FIG. 1). In other words, the sequence formed by sub-steps i), ii), iii), and iv) may be repeated N times.

The entire ALD sequence is carried out at low temperature, that is, at a deposition temperature lower than 250° C., and preferably at a deposition temperature in the range from 20 to 250° C., even more preferably from 50 to 250° C., even more preferably from 50 to 200° C., and even more preferably between 8° and 150° C. The deposition temperature corresponds to the substrate temperature.

Such temperatures ensure the growth of an amorphous layer in ALD regime. The deposited layer is thus perfectly uniform and of low roughness. The thickness and the morphology of the layer are advantageously identical at any point of the substrate. The low roughness guarantees that each crystal which will be formed in the layer at the end of the method will have the same thickness, and that there will be no breakage or discontinuity in the deposit.

Low growth rates during a deposition by ALD allow a better control of the composition of the layer in the case of the forming of alloys with group-5 transition metals (V, Nb, Ta).

Thus, the ALD deposition method not only allows TMD to grow in cavities with a high form factor, but also enables to control the forming of an alloy or of a heterostructure. Indeed, with such a method, it is possible, in a first step, to deposit the different materials in successive layers or as an alloy, and then to carry out the simultaneous crystallization of the different materials in a second step.

In CVD, it is more difficult to obtain alloys of controlled composition, since the precursors are introduced in a mixture and only the most thermodynamically stable composition under the temperature and partial pressure conditions used for deposition is obtained.

At step a), and more particularly during sub-step i), the precursor of the transition metal is selected from the family of oxyhalides for group-6 transition metals typically having formula MO₂X₂ or MOX₄ (X═F, Cl, Br, I) or from the family of halides for group-5 transition metals typically having formula MXₙ (with n in the range from 3 to 5 and X═F, Cl, Br, I).

Preferably, it is selected from among molybdenum oxychlorides, tungsten oxychlorides, vanadium chlorides, niobium chlorides, and tantalum chlorides.

Such precursors are less expensive than other precursors of prior art (for example, amidides or metal-organics). Further, their greater thermal stability enables to implement the process in “batch”-type reactors, better adapted to large-scale production.

The saturation vapor pressure (Vp) of the precursor of metal M will advantageously be higher than 0.1 Torr, and even more preferably higher than 1 Torr, at the temperature used for the deposition process to ensure a sufficient mass transport to the reactor.

Preferably, the precursor is selected from among MoO₂Cl₂, MoOCl₄, WOCl₄, VCl₄, NbCl₅, and TaCl₅. These precursors meet the above-mentioned volatility criterion (Vp>0.1 Torr at the deposition temperature).

As a result of sub-step i), an intermediate layer comprising the transition metal or an intermediate molecule comprising the transition metal is formed on the substrate. This intermediate layer will react with the sulfur-containing molecule during sub-step iii).

During sub-step iii), the sulfur precursor is selected from among hydrogen sulfide, a hydrogen polysulfide, an organosulfur compound containing, preferably, at least 2 sulfur-hydrogen bonds, or any other system allowing the in-situ forming of the mentioned precursors (plasma generator or so-called thermal pre-cracking unit, for example).

Preferably, the sulfur precursor is selected from among hydrogen sulfide, a hydrogen polysulfide, and thiols, preferably dithiols.

Even more preferably, the dithiol is selected from among 1,2-ethanedithiol, 1,2-propanedithiol, and 1,3-propanedithiol.

The precursors of the transition metal or of sulfur may be in solid, liquid, or gaseous form. Precursors in solid or liquid form are stored in a stainless steel saturator.

Preferably, the precursors are introduced into the reactor in vapor form (gas). The temperature to which the precursors are heated in the saturator depends on their volatility. The temperature will be selected so as to reach a sufficient vapor pressure to feed the reactor (typically from approximately 0.1 to 5 torr, that is, between approximately 13.3 and 666.6 Pa).

It is possible to perform the ALD cycle with the same precursors or with different precursors during the different repetitions of the cycle.

For example, to form Mo(V)S₂ alloys or MoS₂/VS₂ heterostructures during the ALD cycle, the MoO₂Cl₂/EDT and/or VCl₄/EDT pairs of precursors may be used.

The deposition temperature of VS₂ is preferably identical to the deposition temperature of MoS₂ (lower than 150° C.) and the same sulfur precursor (EDT) is used, which enables to carry out Mo(V)S₂ deposition sequences where the proportion of vanadium can be perfectly controlled.

Preferably, the sulfur precursor is identical all throughout the process. Preferably, it is 1,2-ethanedithiol (EDT).

The ALD cycle is implemented in a reactor allowing a sequential feeding of the precursors. The precursors are not introduced concomitantly. A purge (sub-steps ii) and iv)) is carried out between each introduction of precursors to drain off precursors which have not reacted during the previous sub-step as well as volatile reaction by-products. The purge is performed with a neutral gas, such as argon or nitrogen.

The working pressure is preferably in the range from 1 mTorr and 50 Torr (that is, between approximately 0.1 Pa and 6,666.1 Pa), and even more preferably between 0.1 and 10 Torr. The working pressure may vary according to the volume and to the sizing of the reactor.

The substrate is, for example, a silicon substrate (in particular a silicon wafer) covered with a thin layer of silica or of any other oxide, nitride, or metal material having a low surface roughness and which does not react with the deposited TMD layer or the reactants used during the deposition, sulfurization, or annealing steps. Alternatively, the growth may take place on another TMD (sulfide, selenide, or tellurium). The exposed surface of the substrate may comprise different areas formed of the different previously-mentioned materials, with a view to the integration of the TMD layer into a microelectronic device.

As already mentioned, the deposit obtained at the end of step a) is amorphous. It is a coordination polymer containing metal-sulfur bonds as well as 1,2-ethanedithiolato ligands. Such a polymer is converted into a highly uniform sulfide layer during the anneal step (step c)).

At the end of step a), depending on the temperature and on the reactants used during the ALD cycle, the obtained thin film may still contain unsubstituted ligands or carbon present in the sulfur precursor. The optional sulfurization step (step b), which can be carried out before or during step c)), enables to guarantee the removal of residual ligands, in other words, that the thin film is exclusively formed of metal-sulfur bonds, and the obtaining of a sulfide with the correct stoichiometry. Another advantage of the sulfurization step is to pre-crystallize the TMD thin film and to give it a better stability in air which enables to limit the forming of metal-oxygen bonds during the transfer to the thermal annealing equipment, and/or, if necessary, during the steps of cleaning of the back side of the substrate.

The temperature of step b) is preferably at a temperature higher than 250° C., preferably at a temperature in the range from 250 to 1,150° C., even more preferably from 300 to 400° C.

The sulfurization step is carried out in the presence of a sulfur-containing compound. The precursors used for this step may be sulfur in its native form or any volatile molecule containing S—H or S—C bonds, used as a dilute vapor in an inert gas, or in a mixture with hydrogen.

Preferably, it may be the same sulfur-containing molecule as that used in the deposition step, which then enables to carry out the sulfurization step directly in the equipment used for the deposition, without venting. For example, the sulfurization of the thin film obtained with the MoO₂Cl₂/EDT pair of precursors to form MoS₂ may be carried out optimally at 360° C. under EDT vapor for a 30 min time period.

Sulfurization step b) may be directly applied to the final alloy or heterostructure. There is no need to repeat a separate sulfurization step between each layer of a different metal. Indeed, the diffusion of sulfur in an amorphous TMD layer is more than sufficient to ensure the sulfurization of the thin layers of a thickness of some ten nanometers within a few minutes.

The implementation of step c) depends on the temperatures used during steps a) and/or b).

Thermal anneal step c) enables to crystallize the TMDs thin film and/or to improve its crystalline quality. It ensures the forming of TMDs crystals oriented in the plane of the substrate and of optimum size.

This step is preferably carried out in an inert atmosphere (N₂, He, or Ar, in particular).

This anneal is carried out at a temperature higher than that used during sulfurization step b). The anneal is typically carried out at a temperature in the range from 400 to 1,150° C., ideally from 650° C. to 950° C.

For example, the temperature of step c) is advantageously 900° C. for MoS₂ or WS₂, such as for example in the case where the targeted application requires an optimum crystallinity of the TMD.

The heat source may be a resistor or any other emissive source (halogen lamp or laser) that can be absorbed by the TMD thin film or any other constituent of the growth substrate.

With such a method, it is possible to manufacture thin films of MS₂ or M′Sx with M a group-6 transition metal and M′ a group-5 transition metal, M(M′)S₂-type alloys, or also heterostructures consisting of a stack of different TMD materials (MS₂/M′Sₓ for example).

More particularly, the obtained device comprises a substrate covered by a thin film or a stack of crystalline thin films of molybdenum, tungsten, vanadium sulfide (VS₂ or VSₓ with x greater than 1 and smaller than 3), niobium, tantalum sulfide, or one of their alloys such as Mo(V)S₂ or W(Nb)S₂.

With such a method, it is possible to obtain layers of different thicknesses according to the targeted application.

The thin film may have a thickness ranging up to 50 nm, or even up to 100 nm, for example, to form metallic contacts made of TMDs (group 5).

The thin layer may have a smaller thickness. For example, it may be a thickness smaller than 20 nm, preferably smaller than 10 nm.

The minimum thickness of the thin film may correspond to the thickness of an atomic monolayer according to the 001 plane, that is, for example 0.65 nm for a MoS₂ monolayer.

The obtained thin films may have very low roughness. The RMS roughness (determined by AFM) may typically be lower than 0.3 nm.

The method is particularly advantageous because it enables to obtain ultra-thin (typically having a thickness smaller than 5 nm), smooth (of low roughness; typically having a roughness lower than 0.3 nm), and continuous layers.

The (001) planes of the TMD crystals are oriented parallel to the plane of the substrate.

The method is easy to industrialize due to its low cost and to the thermal stability of the precursors used.

The method is particularly advantageous to manufacture (micro) electronic devices such as field-effect transistors, memristors, RF switches, and devices for spintronics or quantum computing.

Vanadium, niobium, and tantalum enable to induce a robust p-type doping in MoS₂ and WS₂ materials. Further, VS₂ exhibits a near-ideal lattice match with MoS₂ and WS₂.

It is thus possible to form VS₂/MoS₂ or VS₂/WS₂ heterostructures with very low stress, or Mo(V)S₂ or W(V)S₂ semiconductor alloys capable of exhibiting more advantageous conduction properties than pure MoS₂ and WS₂.

Lamellar vanadium sulfides (VS₂ and V₅S₈) are good conductors (resistivities lower than one mOhm·cm). In particular, VS₂ has a lower contact resistance on MoS₂. The implementation of a sulfide-based contact is also particularly advantageous to avoid damaging a TMD semiconductor based on MoS₂ or WS₂.

Various embodiments and variants have been described. The person skilled in the art will understand that certain features of these various embodiments and variants could be combined, and other variants will become apparent to the person skilled in the art.

Finally, the practical implementation of the modes of realization and variants described is within the reach of the person skilled in the art, based on the functional indications given above.

### ILLUSTRATIVE AND NON-LIMITING EXAMPLES OF DIFFERENT EMBODIMENTS

### Example 1: Deposition of a MoS₂ Layer

The ALD cycle is performed by successively alternating pulses of the MoO₂Cl₂ and EDT (1,2-ethanedithiol) precursors at 100° C.

The temperature of the MoO₂Cl₂ source is 68° C. The temperature of the EDT source is 40° C.

After the forming of the thin film, a sulfurization step is carried out in the presence of EDT for 30 min at 360° C. A rapid thermal anneal (RTP) under N₂ for 30 seconds at 900° C. results in the crystallization of the MoS₂ thin film.

### Example 2: Deposition of a Vanadium Sulfide Layer

The ALD cycle is performed by successively alternating pulses of the VCl₄ and EDT (1,2-ethanedithiol) precursors at 100° C.

The temperature of the VCl₄ source is 30° C. The temperature of the EDT source is 40° C.

After the forming of the thin layer, a sulfurization step is carried out in the presence of EDT for 30 min at 360° C., with no venting between the deposition and sulfurization steps.

The resistivity of the vanadium sulfide layer obtained after sulfurization is approximately 1,000 μOhm·cm for a 10-nm thickness.

A thermal anneal after the sulfurization step enables to crystallize the material and to give it a better resistance to oxidation. The material keeps its metallic properties at annealing temperatures ranging up to 950° C., with a non-linear resistivity variation.

### Example 3: Deposition of a Mo(V)S₂ Layer (Vanadium-Doped Molybdenum Sulfide)

The layer is obtained by ALD by using the MoO₂Cl₂, VCl₄, and EDT (1,2-ethanedithiol) precursors at a 100° C. temperature. The precursors are introduced according to sequence [(MoO₂Cl₂/EDT)_{X}/(VCl₄/EDT)]_{Y} with x and y positive integers.

The temperature of the MoO₂Cl₂ source is 68° C. The temperature of the VCl₄ source is 30° C. The temperature of the EDT source is 40° C.

Once the forming of the thin layer, a sulfurization step is carried out in the presence of EDT for 30 min at 360° C.

A rapid thermal anneal (RTP) under N₂ for 30 seconds at 900° C. results in the crystallization of the Mo(V)S₂ thin film. The resistivity of the MoS₂ layer is all the smaller as the amount of incorporated vanadium is significant.

### Example 4: Forming of a MoS₂/VS_{X} Heterostructure

The layers of the heterostructure were deposited by ALD at 100° C. by abutting the sequences described in examples 1 and 2 and adjusting the number of ALD cycles to obtain 2 atomic monolayers of MoS₂ coated with 5 nm of vanadium sulfide. The heterostructure was then sulfurized at 350° C. and crystallized by rapid thermal anneal at 850° C.

The obtained heterostructure was characterized by transmission electron microscopy (STEM-HAADF), thus highlighting the forming of a MoS₂ (1 nm)/VSₓ (5 nm) stack (FIG. 2).

1. Method of vapor deposition of a sulfide layer of a transition metal or of one of its alloys for the forming of MS₂/M′Sx heterostructures or of M(M′)S₂ alloys with M a group-6 transition metal and M′ a group-5 transition metal, the method comprising a step of atomic layer deposition according to the following cycle:
exposing a substrate to a precursor of a transition metal, whereby an intermediate layer is formed on the substrate,
purging the reactor,
exposing the intermediate layer to a precursor of sulfur,
purging the reactor,
the substrate being at a temperature in the range from 20° C. to 250° C. during the cycle,
the cycle may be repeated several times, where the precursor of the transition metal and/or the precursor of sulfur may be identical or different during the repetitions of the cycle,
the precursor of the transition metal being selected from among molybdenum oxyhalides, tungsten oxyhalides, vanadium halides, niobium halides, and tantalum halides.

2. Method according to claim 1, wherein the precursor of the transition metal is selected from among MoO₂Cl₂, MoOCl₄, WOCl₄, VCl₄, NbCl₅, and TaCl₅.

3. Method according to claim 1, wherein the precursor of sulfur is selected from among hydrogen sulfide, hydrogen polysulfides, and thiols, preferably dithiols.

4. Method according to claim 1, wherein the precursor of sulfur is selected from among 1,2-ethanedithiol, 1,2-propanedithiol, and 1,3-propanedithiol.

5. Method according to claim 1, wherein, after the atomic layer deposition step, the method comprises a sulfurization step during which the substrate is exposed to a sulfur-containing molecule having at least one sulfur-hydrogen or sulfur-carbon bond, at a temperature in the range from 250° C. to 1,150° C., preferably from 300° C. to 400° C.

6. Method according to claim 1, wherein the sulfur molecule is a dithiol, preferably 1,2-ethanedithiol.

7. Method according to claim 1, wherein, after the atomic layer deposition step, or after the sulfurization step, an anneal step is implemented.

8. Method according to claim 1, wherein the anneal step is carried out in an inert atmosphere at a temperature in the range from 400° C. to 1,150° C., preferably from 650° C. to 950° C.

9. Method according to claim 1, wherein the substrate is at a temperature in the range from 50° C. to 150° C., preferably from 80° C. to 120° C., during the cycle.

10. Method according to claim 1, wherein the precursor of the transition metal is selected from among MoO₂Cl₂, MoOCl₄, WOCl₄, and VCl₄ and wherein the precursor of sulfur is 1,2-ethanedithiol.

11. Device comprising a substrate covered by a stack of crystalline thin films forming an MS₂/M′Sx heterostructure or by a crystalline thin film of an M(M′)S₂ alloy with M a group-6 transition metal and M′ a group-5 transition metal, the crystalline thin film(s) being of molybdenum, tungsten, vanadium, niobium, tantalum sulfide or of one of their alloys such as Mo(V)S₂ or W(V)S₂, the thin film(s) having a thickness smaller than 100 nm, preferably smaller than 20 nm, even more preferably smaller than 10 nm, the crystals of the thin film(s) being oriented, their (001) crystallographic plane being parallel to the plane of the substrate.
